(19) United States
(12) Patent Application Publication
(10) Pub. No.: US 2005/0199924 A1
(43) Pub. Date: Sep. 15, 2005

(54) Optimized ferroelectric material crystallographic texture for enhanced high density feram

(76) Inventors: Glen R. Fox, Colorado Springs, CO (US); Sanjeev Aggarwal, Plano, TX (US); Richard A. Bailey, Colorado Springs, CO (US)

Correspondence Address: TEXAS INSTRUMENTS INCORPORATED, P O BOX 655474, M/S 3999, DALLAS, TX, 75265, US

(21) Appl. No.: 10/797,503

(22) Filed: Mar. 10, 2004

(51) Int. Cl. H01L 29/76

(52) U.S. Cl. 257/295; 257/306; 257/310

(57) ABSTRACT

Ferroelectric capacitors (C_{FE}) are provided, having upper and lower conductive electrodes (22, 18) spaced along an axis (48), and a ferroelectric material (20) between the electrodes, where the ferroelectric material (20) comprises unit cells (200) individually comprising an elongated dimension (c), and where 50-90% of the unit cells in the ferroelectric material are oriented with elongated dimensions substantially parallel to the axis. Methods (100) are provided for fabricating ferroelectric capacitors in a wafer, comprising forming (112) a ferroelectric material above a lower electrode material, the ferroelectric material comprising unit cells with an elongated dimension, wherein 50-90% of the unit cells are oriented with elongated dimensions substantially normal to an upper surface of the wafer.

### RELATED APPLICATION

This application is related to U.S. patent application Ser. No. 10/356,114, filed on Jan. 30, 2003, entitled METHOD OF MAKING A HAZE FREE PZT FILM, the entirety of which is hereby incorporated by reference as if fully set forth herein.

### FIELD OF INVENTION

The present invention relates generally to semiconductor devices and more particularly to ferroelectric capacitors and methods for fabricating ferroelectric capacitors with controlled crystallographic texture in a semiconductor device.

### BACKGROUND OF THE INVENTION

Memory is used for storage of data, program code, and/or other information in many electronic products, such as personal computer systems, embedded processor-based systems, video image processing circuits, portable phones, and the like. Memory cells may be provided in the form of a dedicated memory integrated circuit (IC) or may be embedded (included) within a processor or other IC as on-chip memory. Ferroelectric memory, sometimes referred to as “FRAM” or “FERAM”, is a non-volatile form of memory commonly organized in single-transistor, single-capacitor (1T1C) or two-transistor, two-capacitor (2T2C) configurations, in which each memory cell includes one or more access transistors and one or more ferroelectric capacitors for storing data. The non-volatility of an FERAM memory cell is the result of the bi-stable characteristic of the ferroelectric material in the cell capacitor(s), wherein the ferroelectric material has multiple stable polarization states.

Ferroelectric memory cells are often fabricated in stand-alone memory integrated circuits (ICs) and/or in logic circuits having on-board non-volatile memory (e.g., microprocessors, DSPs, communications chips, etc.). 1T1C ferroelectric memory cells typically comprise a ferroelectric (FE) capacitor that stores a binary data bit, and a cell access transistor, typically a MOS device, that selectively connects the FE capacitor to one of a pair of complimentary bitlines, with the other bitline being connected to a reference voltage. The individual cells are commonly organized as individual bits of a corresponding data word, where the cells of a given word are accessed concurrently by activation of platelines and wordlines by address decoding circuitry. The cells are typically organized in an array, such as folded-bitline, open-bitline, etc., wherein the individual cells are selected by plateline and wordline signals from address decoder circuitry, with the data being read from or written to the cells along bitlines using sense amp and other I/O circuits. In a typical 1T1C memory cell, a ferroelectric capacitor is coupled between a plateline signal and a source/drain of the MOS cell transistor, the other source/drain is connected to a bitline, and the transistor gate is connected to a wordline control signal to selectively couple the capacitor with the bitline during read and write operations.

Such ferroelectric memory devices provide non-volatile data storage where the ferroelectric cell capacitors are constructed using ferroelectric dielectric material situated between two conductive electrodes, which may be polarized in one direction or another in order to store a binary value. The ferroelectric effect allows for the retention of a stable polarization in the absence of an applied electric field due to the alignment of internal dipoles within Perovskite crystals in the ferroelectric material. This alignment may be selectively achieved by application of an electric field that exceeds the coercive field of the material. Conversely, reversal of the applied field reverses the internal dipoles. The response of the polarization of a ferroelectric capacitor to the applied voltage may be plotted as a hysteresis curve.

Data in a ferroelectric data cell is typically read by connecting a reference voltage to a first bitline and connecting the cell capacitor between a precharged complimentary bitline and a plateline signal voltage. This provides a differential voltage on the bitline pair, which is connected to a sense amp circuit. The reference voltage is typically supplied at an intermediate voltage between the voltage associated with a capacitor programmed (e.g., polarized) to a binary “0” and that of the capacitor programmed to a binary “1”. The polarity of the sensed differential voltage thus represents the data stored in the cell, which is buffered and applied to a pair of local IO lines. The transfer of data between the ferroelectric memory cell, the sense amp circuit, and the local data bitlines is controlled by various access transistors, with switching signals being provided by control circuitry in the device.

Connection of the ferroelectric cell capacitor between a plateline signal and a precharged bitline during a read operation causes an electric field to be applied to the cell capacitor. If the field is applied in a direction so as to switch or reverse the internal dipoles, more charge will be moved than if the dipoles are not reversed. As a result, the sense amplifier can measure the charge applied to the cell bit lines and produce either a logic “1” or “0” at the sense amp terminals. Since reading the cell data is a destructive operation, the sensed data is then restored to the cell following each read operation. To write data to the cell, an electric field is applied to the cell capacitor by a sense amp or write buffer to polarize it to the desired state. Ferroelectric memories provide certain performance advantages over other forms of non-volatile data storage devices, such as flash and EEPROM type memories, for example, short programming (e.g., write access) times and low power consumption.

One performance measure for ferroelectric memory is the signal margin provided between the programmed “0” and “1” data states, which is related to the switched or switchable polarization P_{sw} of the ferroelectric material used in the cell capacitor, usually expressed in uCcm⁻². In this regard, the signal margin is related to the amount of charge transferred to the precharged bitline when the plateline pulse is applied to the selected cell capacitor, wherein the ferroelectric capacitor switches polarity as a result of the plateline pulse for one data state, and does not change polarity for the other binary data state. As the signal margin decreases, the ability to reliably discern the programmed data state is reduced.

In addition to switched polarization, the signal margin is also affected by the amount of ferroelectric material fatigue over repeated access after the cell has been programmed, wherein the amount of switched charge during a read operation may decrease with number of cycles. Another performance metric is the retention, which is a measure of the relaxation of the ferroelectric material over time of programmed data when power is removed from the memory cells. As semiconductor devices are scaled to smaller and smaller dimensions and as operating voltages and power levels are reduced, it is desirable to control and/or improve ferroelectric memory data retention and signal margin.

### SUMMARY OF THE INVENTION

The following presents a simplified summary in order to provide a basic understanding of one or more aspects of the invention. This summary presents one or more concepts of the invention in a simplified form as a prelude to the more detailed description that is presented later and is not an extensive overview of the invention. In this regard, the summary is not intended to identify key or critical elements of the invention, nor does the summary delineate the scope of the invention.

The invention relates to semiconductor devices and ferroelectric capacitors, as well as fabrication methods therefor, in which the crystallographic texture of the ferroelectric material is controlled during formation, to facilitate improved capacitor performance with respect to signal margin and data retention in memory and other semiconductor devices.

In one aspect of the invention, semiconductor devices and ferroelectric capacitors therefor are provided, wherein the ferroelectric capacitor comprises upper and lower conductive electrodes and a ferroelectric material between the electrodes. The ferroelectric material comprises unit cells having an elongated dimension (e.g., such as tetragonal PZT unit cells which are elongated in the [001] direction in the examples illustrated below), where 50-80% of the unit cells in the ferroelectric material are oriented with elongated dimensions substantially normal to the capacitor electrodes (e.g., parallel to the capacitor axis). The provision of PZT or other ferroelectric material with controlled crystallographic texture in the range of 50-90% along the [001] direction is believed to provide enhanced capacitor switched polarization without significant detrimental relaxation effects, thereby improving signal margin for data state detection in ferroelectric memory applications, as well as providing enhanced data retention. The invention thus facilitates ferroelectric memory devices with improved performance compared with conventional ferroelectric capacitors having randomly oriented PZT with uncontrolled crystallographic texture.

Another aspect of the invention provides a method of fabricating a ferroelectric capacitor, wherein a conductive lower electrode material is formed above a semiconductor body, and a ferroelectric material is formed above the lower electrode material. The ferroelectric material comprises unit cells, such as tetragonal PZT unit cells, that individually comprise an elongated dimension (e.g., [001] dimension), wherein 50-90% of the unit cells are oriented with elongated dimensions substantially parallel to an axis of the capacitor (e.g., normal to an upper surface of the semiconductor body in vertical capacitor implementations). In one example, the ferroelectric material formation includes preheating the wafer in a substantially non-oxidizing ambient, such as Argon (Ar). The ferroelectric material is then deposited through metal organic chemical vapor deposition (MOCVD) or CVD or ALD or other deposition processes at a pressure of about 8 Torr after preheating.

The following description and annexed drawings set forth in detail certain illustrative aspects and implementations of the invention. These are indicative of but a few of the various ways in which the principles of the invention may be employed.

### BRIEF DESCRIPTION OF THE DRAWINGS

FIG. 1 is a partial side elevation view in section illustrating a portion of a semiconductor device having a ferroelectric capacitor with optimized PZT crystallographic texture coupled with a MOS transistor to form a 1T1C ferroelectric memory cell in accordance with the present invention;

FIGS. 2A-2E are partial side elevation views in section illustrating formation of the exemplary ferroelectric capacitor with optimized PZT crystallographic texture in the device of FIG. 1;

FIG. 3 is a flow diagram illustrating an exemplary method of fabricating ferroelectric capacitors in accordance with the invention;

FIG. 4A is a simplified perspective view illustrating a generally cubic PZT unit cell;

FIG. 4B is a simplified perspective view illustrating a PZT unit cell having tetragonal distortion in the [001] direction;

FIG. 4C is a partial side elevation view along the [100] direction illustrating the tetragonal displacement or distortion of the Lead (Pb) and Zirconium (Zr) or Titanium (Ti) relative to the Oxygen (O) in the PZT unit cell of FIG. 4B; and

FIGS. 5A-5E are plots of various performance data illustrating performance optimizations and test data obtained through control of ferroelectric capacitor material volume orientation and crystallographic texture in accordance with the invention.

### DETAILED DESCRIPTION OF THE INVENTION

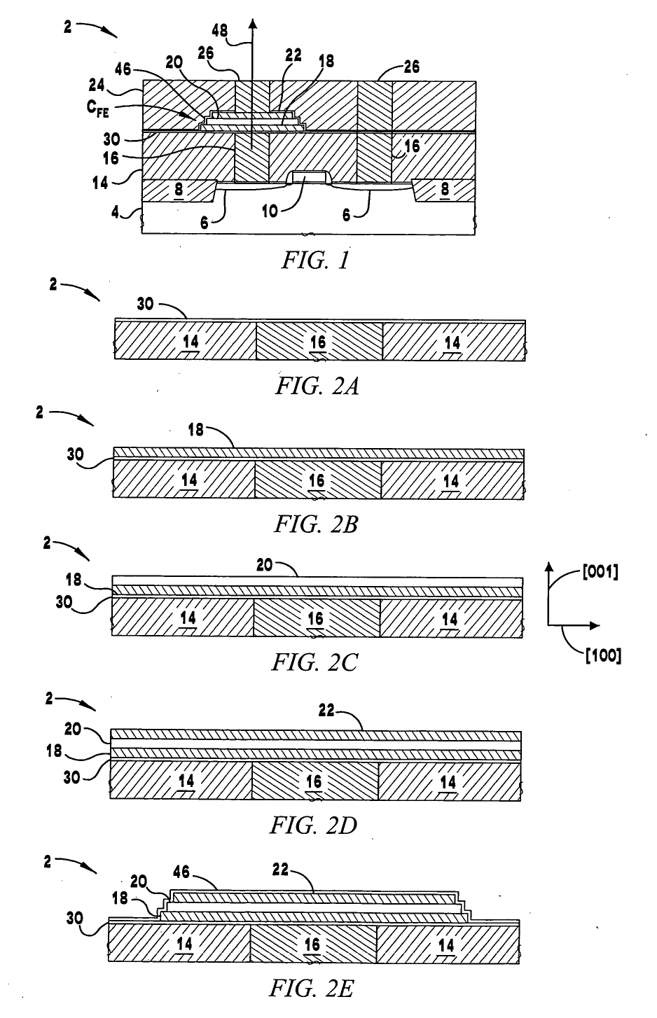

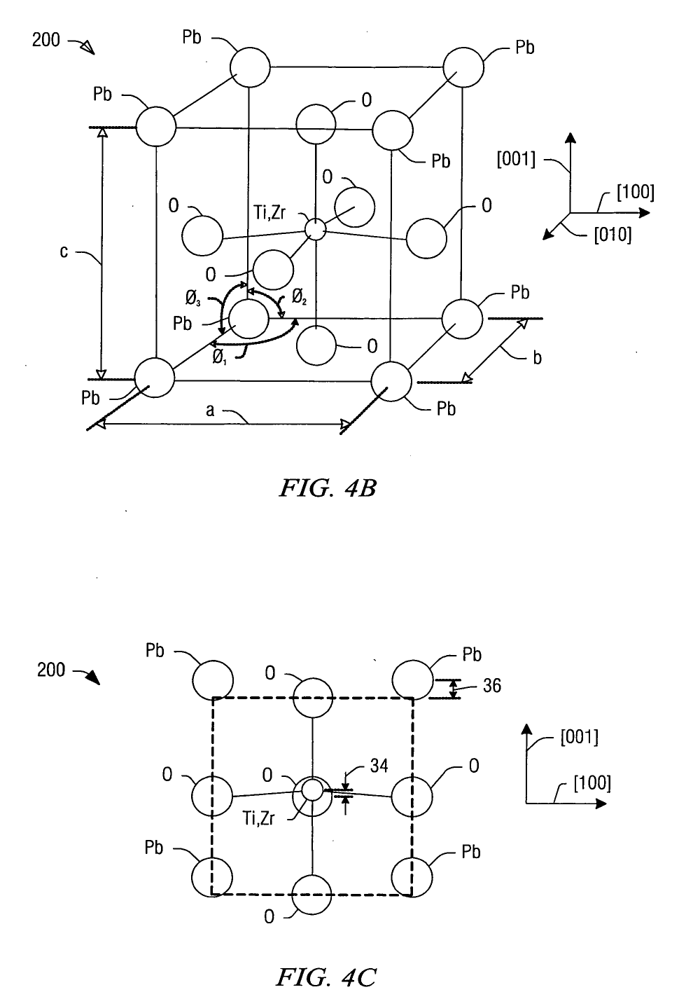

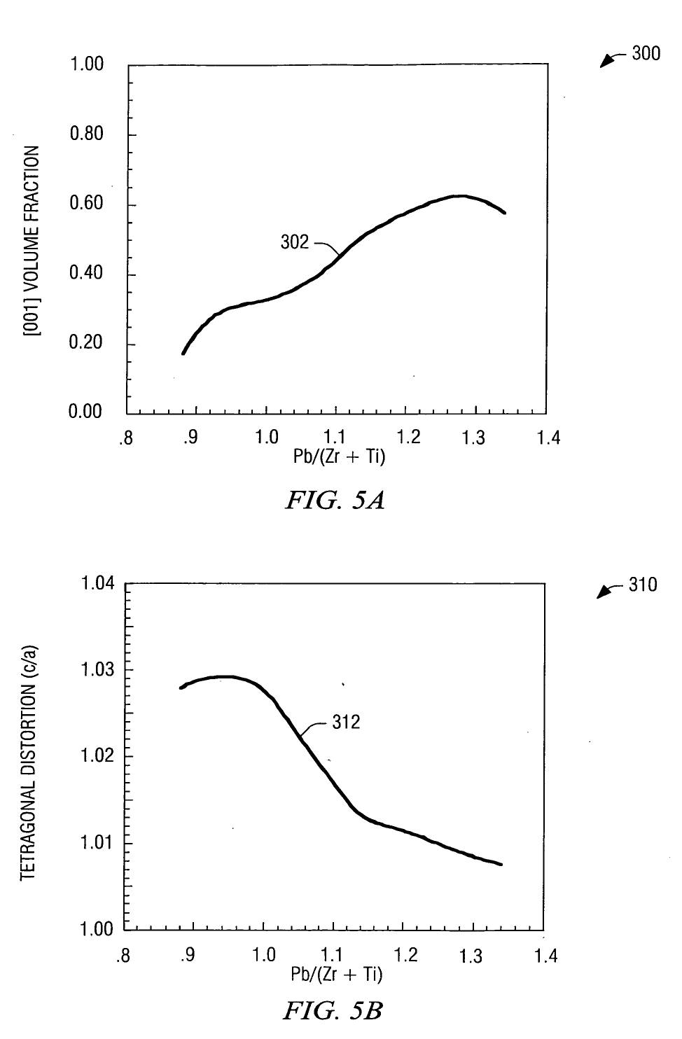

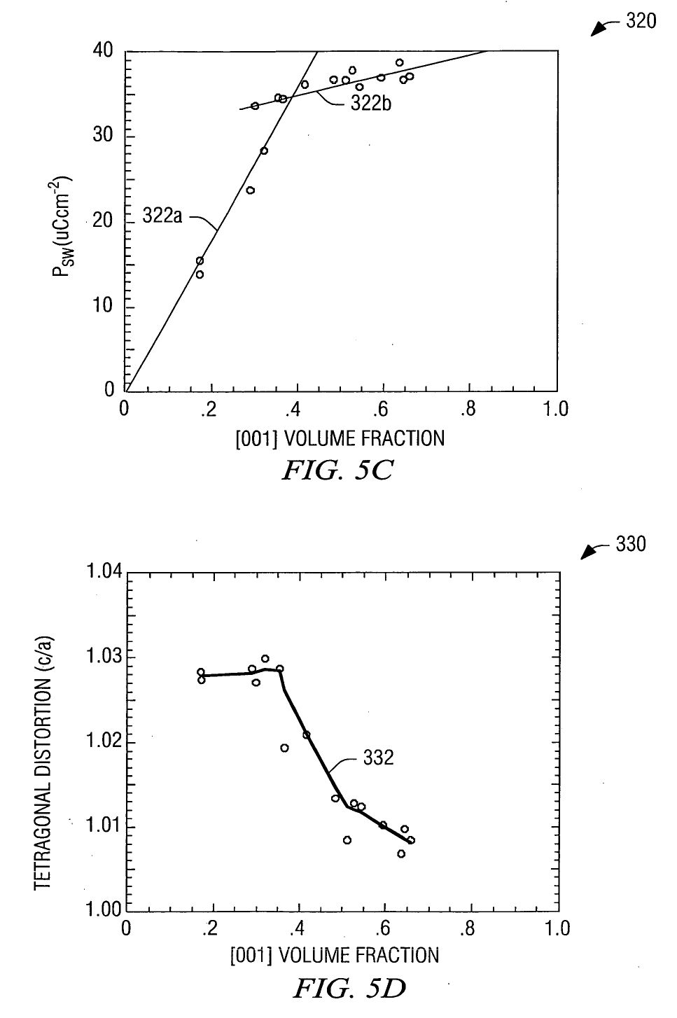

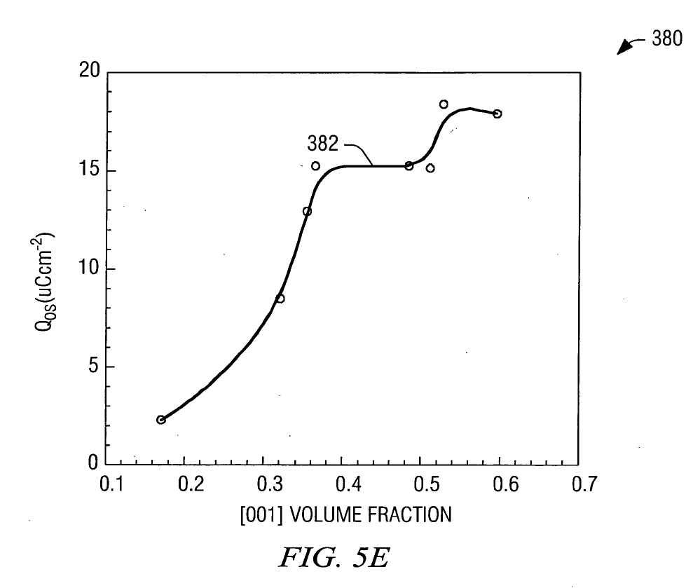

The present invention will now be described with reference to the attached drawing figures, wherein like reference numerals are used to refer to like elements throughout. The invention relates to semiconductor device fabrication and the formation of ferroelectric capacitors with optimized ferroelectric material crystallography. The invention may be carried out in any type of semiconductor device, for example, devices having memory cells with ferroelectric cell capacitors or other devices in which ferroelectric capacitors are used. The various aspects and advantages of the invention are hereinafter illustrated and described in conjunction with the drawings, wherein the illustrated structures are not necessarily drawn to scale. FIGS. 1, 2A-2E, and 3 illustrate an exemplary ferroelectric capacitor having an optimized ferroelectric material crystallography, as well as an exemplary fabrication method therefor in accordance with various aspects of the present invention. FIGS. 4A-4C illustrate a ferroelectric PZT unit cell crystallography and tetragonal distortion or elongation thereof, and FIGS. 5A-5E illustrate various data graphs showing ferroelectric material properties and performance data related to optimizing ferroelectric material crystallography.

In FIG. 1, a semiconductor device 2 is illustrated having a 1T1C ferroelectric memory cell with a cell transistor formed in/on a silicon substrate 4 and a ferroelectric capacitor C_{FE}. The invention may be practiced in devices fabricated using any semiconductor device wafer, including silicon substrates, SOI wafers, etc. As illustrated in FIG. 1, the cell transistor includes a gate structure 10 situated above a channel region of the substrate 4, with source/drains 6 formed on either side of the channel in an active region located between isolation structures 8. A poly-metal dielectric (PMD) 14 is provided above the substrate 4 to cover the cell transistor, where bitline and plateline contacts 16 are formed through the PMD 14 to connect with the cell transistor source/drains 6 (the electrode of the gate 10 forms a conductive array wordline structure in this example).

The exemplary ferroelectric capacitor C_{FE} is formed above the plateline source/drain contact 16, where the capacitor C_{FE} comprises a first or lower conductive non-perovskite electrode 18, a ferroelectric material 20 having controlled crystallographic orientation in accordance with the invention, and a conductive second or upper non-perovskite electrode 22. An optional lower diffusion barrier layer 30 is formed prior to fabrication of the ferroelectric capacitor C_{FE}, and an optional sidewall diffusion barrier 46 is formed over the capacitor C_{FE} for inhibiting hydrogen diffusion during fabrication. A first inter-level or inter-layer dielectric (ILD0) 24 is formed over the barrier 46, and conductive contacts 26 are formed through the dielectric 24 (and through the barrier 46) to couple with the upper capacitor electrode 22 (plateline) and with the bitline contact 16 in the PMD level 14.

Referring also to FIGS. 4A-4C, in accordance with an aspect of the present invention, the crystallographic texture of the ferroelectric material 20 is controlled during formation, such that about 50-90% of the unit cells in the lattice structure thereof are oriented substantially parallel to the axis 48 of the capacitor C_{FE} (e.g., substantially normal to the upper surface of the substrate 4) to facilitate enhanced capacitor switched polarization and data retention in the device 2. FIG. 4A illustrates a perspective view of a generally cubic PZT unit cell 200, in which first, second, and third dimensions a, b, and c, respectively, are generally equal along orthogonal directions [100], [010], and [001], respectively, and where the angles of the structure φ₁, φ₂, and φ₃ are generally equal.

FIGS. 4B and 4C illustrate a generally tetragonal PZT unit cell, in which the c-dimension (e.g., along the [001] direction) is elongated, and the dimensions a and b are generally equal to one another and less than c. In the illustrated example, the Titanium (Ti) or Zirconium (Zr) ion is offset or displaced relative to the Oxygen (O) ions by a distance 34 (FIG. 4C, e.g., about 0.3 Å in one example), and the Lead (Pb) ions are displaced by a distance 36 (e.g., about 0.47 Å) relative to the Oxygen ions. The inventors have found that the elongation of the c-dimension (e.g., along the [001] direction) is given by a ratio c/a generally between about 1.01 and 1.04.

The inventors have appreciated a performance tradeoff in ferroelectric memory capacitors that can be optimized through control of the ferroelectric material crystallographic texture. On one hand, increased volume orientation of the ferroelectric material 20 along the [001] direction improves data retention and switched polarization (P_{sw} typically expressed in units of uCcm⁻²), as illustrated below in FIG. 5C. However, at higher levels of switched polarization, a ferroelectric capacitor, after being programmed to a polarization state, will tend to relax over time to a metastable equilibrium at a lower level of polarization. Moreover, the amount of such relaxation is believed to increase with the amount of initial polarization. In this regard, the inventors have appreciated that maximizing the switched polarization P_{sw}, for example, by forming the ferroelectric material 20 with 100% volume orientation in the [001] direction, could lead to undesirably large relaxation levels in the capacitor C_{FE}. As a result, design of sense amp circuitry and the sense margin thereof would need to accommodate a large variance in the signal obtained from the capacitor C_{FE} during read operations.

Accordingly, the inventors have found that forming the ferroelectric material 20 with about 50-90% by volume of the unit cells oriented with the elongated c-dimension substantially parallel to the capacitor axis 48 (substantially normal to the plane of the substrate 4 in the device 2, referred to herein as volume orientation in the [001] direction) can provide optimal performance with respect to switchable polarization for enhanced signal margin and data retention, without significant penalty in polarization relaxation effect. In another preferred embodiment of the invention, [001] volume orientation of 50-70% has been found to further optimize such performance measures. In still another possible implementation, [001] volume orientation of 60-70% provides significant performance advantages, particularly when compared with conventional PZT ferroelectric capacitors having generally random crystallographic texture. In one particular example illustrated below in FIG. 5D, a [001] volume fraction of about 60% with tetragonal distortion of about 1% (e.g., c/a ratio of about 1.01) provides an optimized PZT film 20. In this regard, the ferroelectric capacitors and methods of the present invention can be employed such that signal margin and data retention thereof over time and temperature, and fatigue over repeated access cycles are enhanced through optimizing the crystallographic texture of PZT and other ferroelectric material 20, where the crystalline orientation or texture can be measured using x-ray diffraction or other suitable techniques.

In the case of PZT and other perovskite ferroelectric materials, the unit cell is a tetragonal arrangement that is close to cubic over certain temperature ranges, with an elongation or tetragonal distortion in the [001] direction of about 1 to 4%, wherein the c-dimension in FIGS. 4A-4C is typically about 3% larger than the a and b dimensions. In storing data to a ferroelectric material 20, the applied fields are along the axis 48 of the capacitor C_{FE} (FIG. 1), wherein the data storage results from polarization of unit cells having the elongated dimension “c” (e.g., the [001] direction) substantially parallel to the axis 48, such as within about 10 degrees of being exactly parallel in one example.

The exemplary PZT material 20 is made up of cations and anions, including Pb, Zr, Ti and oxygen, where the Zr and Ti are interchangeable, and they sit close to the very center of the cell, as illustrated in FIGS. 4A and 4B. In the illustrated examples, the PZT material 20 includes tetragonal compositions in which the zirconium Zr content is from about 0-52% (e.g., and the titanium Ti constitutes about 100-48%), where the Zr constitutes above 10-40% in one preferred implementation. The material 20, moreover, may be doped with one or more impurities, for example, including but not limited to lanthanum (La) and/or niobium (Nb). The Zr/Ti ion is believed to shift off-center upon application of programming voltages to the capacitor electrodes 18 and 22, either upward or downward relative to the Oxygen in the [001] direction during memory access operations, thus causing polarization for storing or retrieving data. The polarization results in a dipole, wherein the sum of the dipoles of [001] oriented unit cells within the material 20 results in a macroscopic polarization.

The inventors have further appreciated that the lower electrode 18 is advantageously made from a substantially non-oxidized non-perovskite material, such as Iridium, in order to facilitate fabrication of PZT with a volume fraction of [001] oriented cells in the range of 50-90%. In this regard, the inventors have found that the lower electrode material 18 on which the ferroelectric 20 is formed, and in particular, the amount of oxygen thereof, may contribute to or detract from the goal of achieving a controlled ferroelectric crystallographic texture. Oxides in the lower electrode 18 are believed to promote formation of randomly oriented ferroelectric 20, whereas employing Iridium or other substantially non-oxidized electrode material 18 may facilitate forming ferroelectric material 20 of controlled volume orientation in the [001] direction.

For example, preheating the Ir bottom electrode wafer in an oxygen ambient prior to deposition of the ferroelectric material leads to the formation of an iridium oxide layer. The oxidizer gases such as oxygen, nitrous oxide during the ferroelectric material deposition over an Iridium bottom electrode may lead to formation of an Iridium oxide IrO, which then acts as a template for ferroelectric crystal formation. Since IrO basically consists of cubic unit cells, PZT deposited onto IrO tends to template off the cubic IrO structure, and forms more randomly oriented PZT cells than is desirable. Although Ir is also not perfectly matched to the desired [001] PZT crystallography, the inventors have found that the mismatch between Ir and PZT is more than that between IrO and PZT, and is significant enough that the deposited PZT material 20 does not tend to conform itself to the Ir. As a result, PZT material 20 formed over Ir or other non-oxidized lower electrode material 18 tends to grow in its own preferred state, which is generally aligned with the elongated dimensions being substantially parallel to the capacitor axis 48.

In addition, the inventors have found that controlling the deposition chamber pressure in preheating the wafer and/or in depositing the ferroelectric material 20 advantageously facilitates control of the crystallographic texture. In one example, the deposition chamber is controlled at a pressure of 6-10 Torr, such as about 8 Torr, to preheat the wafer at about 600-670 degrees C. in a non-oxidizing ambient (e.g., Argon) with no precursors flowing in the chamber. Subsequently, suitable precursors are introduced into the chamber (e.g., PbO+ZrO₂+TiO₂ in one example) to form PZT ferroelectric material 20 over the electrode 18 while maintaining the chamber pressure at 6-10 Torr, such as about 8 Torr. In this example, the inventors have found that the ferroelectric material 20 can be deposited with a volume fraction of about 50-80% oriented with the elongated cell dimension substantially parallel to the capacitor axis 48. In other preferred implementations, the fabrication process can be controlled to form ferroelectric materials 20 having [001] volume orientations of about 50-70% in one example, and about 60-70% in another example.

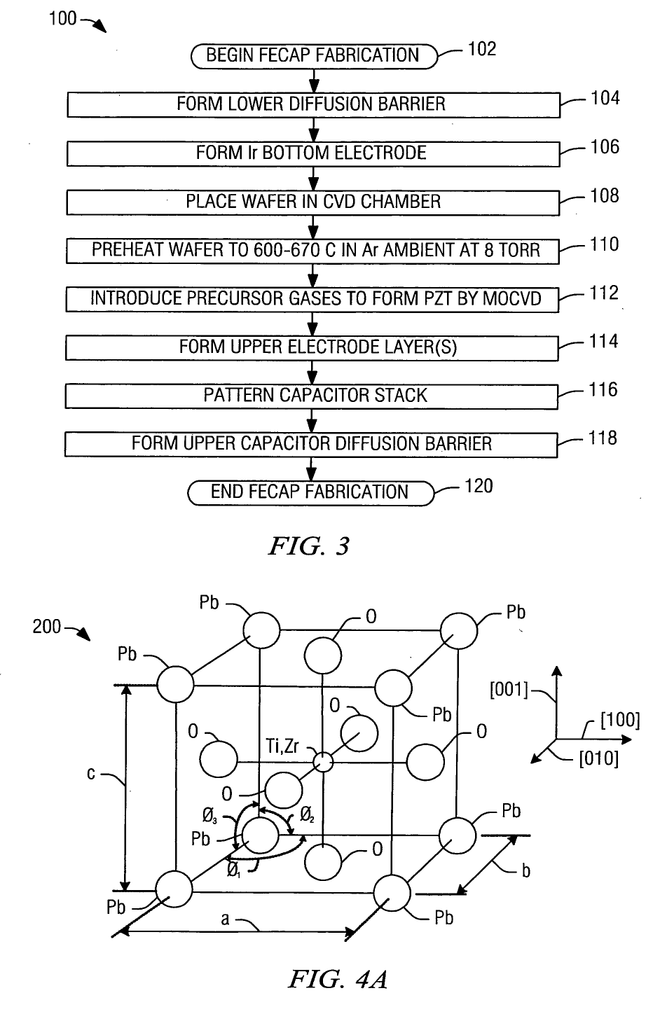

FIGS. 2A-2E illustrate formation of the ferroelectric capacitor stack structure C_{FE} in the exemplary device 2, and FIG. 3 illustrates an exemplary method 100 for fabricating ferroelectric capacitors in accordance with the present invention. Although the method 100 is illustrated and described below as a series of acts or events, it will be appreciated that the present invention is not limited by the illustrated ordering of such acts or events. For example, some acts may occur in different orders and/or concurrently with other acts or events apart from those illustrated and/or described herein, in accordance with the invention. In addition, not all illustrated steps may be required to implement a methodology in accordance with the present invention. Furthermore, the methods according to the present invention may be implemented in association with the devices and systems illustrated and described herein as well as in association with other structures not illustrated.

Beginning at 102 in FIG. 3 after formation of the PMD dielectric 14 and contacts 16, an optional lower titanium aluminum nitride (TiAIN) diffusion barrier layer 30 is formed at 104 over the PMD 14 and over the contact 16 in the device 2 of FIG. 2A. At 106, a single or multi-layer bottom electrode 18 is formed to any suitable thickness by any desired deposition process, as illustrated in FIG. 2B. In a preferred implementation, the electrode 18 is a non-oxide material, such as Iridium, although other materials can be used. The wafer is placed in a chemical vapor deposition (CVD) chamber at 108, and is preheated to about 600-670 degrees C. in a non-oxidizing ambient at 110, with no precursors flowing in the deposition chamber. In one example, the pressure is controlled during the preheat at 110 to 6-10 Torr, such as about 8 Torr, wherein the non-oxidizing ambient includes Argon, but substantially no oxygen.

At 112, a metal organic CVD (MOCVD) process is begun by introduction of suitable precursor gases (e.g., PbO+ZrO₂+TiO₂), to form PZT or other ferroelectric material 20 over the bottom electrode 18, as illustrated in FIG. 2. In accordance with the invention, the deposition at 110 is controlled so as to provide a ferroelectric crystallographic texture having about 50-90% of the cells oriented with elongated dimensions (e.g., the c-dimension in FIGS. 4B and 4C, and the [001] direction indicated in FIG. 2C) substantially normal to an upper surface of the semiconductor body 4. In the preferred implementation, the MOCVD deposition at 112 is performed while the chamber pressure is maintained at about 6-10 Torr, such as about 8 Torr in one example, to form the material 20 with a [001] volume orientation of about 50-70%, about 60-70% in another example.

Thereafter at 114, the upper conductive electrode 22 is formed, as illustrated in FIG. 2D. The upper electrode 22 may be formed at 114 to any desired thickness using any suitable deposition processes, and may be a single or multi-layer structure within the scope of the invention, such as an Ir/IrO structure. At 116, a hardmask (not shown) is formed and patterned, and then used in a capacitor stack etch process to define a capacitor stack (e.g., ferroelectric capacitor C_{FE}), as illustrated in FIG. 2E. An optional upper diffusion barrier 46 is then formed at 118 over the capacitor C_{FE}, which may be any suitable material or materials and thickness, and the method 100 ends at 120. Thereafter, metalization and other back end processing (not shown) is performed to complete the semiconductor device 2.

FIGS. 5A-5E illustrate performance data illustrating performance optimizations and test data obtained through control of ferroelectric capacitor material volume orientation and crystallographic texture in accordance with the invention. In FIG. 5A, a plot 300 illustrates a curve 302 showing [001] volume orientation vs. PZT precursor gas content during deposition of PZT material 20, wherein the ratio of Lead to the sum of Zirconium and Titanium is varied (e.g., PbO/(ZrO₂+TiO₂), indicated as Pb/(Zr+Ti) in the Figures). As can be seen in FIG. 5A, the [001] volume fraction generally increases with increased ratio of Pb/(Zr+Ti) until a ratio of about 1.27 is reached. A plot 310 in FIG. 5B shows a curve 312 the relationship of PZT tetragonal distortion (e.g., c-dimension elongation along the direction [001] in FIG. 4B) to the precursor gas mixture, wherein the tetragonal distortion generally decreases as the ratio Pb/(Zr+Ti) increases. The inventors have appreciated from these curves 302 and 312 that for patterned ferroelectric capacitors as shown in FIG. 1, while [001] volume orientation increases, the tetragonal distortion of the unit cells decreases with increased Pb/(Zr+Ti) ratio, wherein the precursor gas ratio can be tuned to provide the desired [001] volume fraction in the ferroelectric material 20.

In addition, as illustrated in FIGS. 5C and 5D, the inventors have appreciated that ferroelectric capacitor switchable polarization P_{sw} increases and tetragonal distortion decreases with increased [001] volume fraction in PZT materials. A plot 320 in FIG. 5C illustrates P_{sw} vs. [001] volume fraction, where the curve includes a first portion 322a for [001] volume fractions up to about 35%, and thereafter follows a second slope 322b, wherein switchable polarization values of about 35 uCcm⁻² or more are obtained in this example for [001] volume fractions of 50-90%. In FIG. 5D, a plot 330 shows a curve 332 illustrating tetragonal distortion (e.g., the ratio of c/a dimensions), which decreases as a function of [001] volume fraction above about 35%.

In this particular case, an optimized PZT material 20 could comprise, for example, a [001] volume fraction of about 60% with a tetragonal distortion (e.g., c-direction elongation) of about 1% (e.g., c/a ratio of about 1.01). However, other materials are contemplated within the scope of the invention having different tetragonal distortion vs. [001] volume fraction relationships. For instance, another film could have higher tetragonal distortion values than those illustrated in FIG. 5D, in which case an optimal material 20 would have a [001] volume fraction in the range of about 50-90%, although such a film may have a tetragonal distortion of as high as about 10% or more. All such variant implementations of ferroelectric films with [001] volume fractions of about 50-90% are contemplated as falling within the scope of the present invention.

FIG. 5E provides a plot 380 illustrating a curve 382 of opposite state switched polarization Qₒₛ in uCcm⁻² as a function of [001] volume fraction. As can be seen in FIG. 5E, the plot 382 includes a first plateau at about 15 uCcm⁻² from about 35-50% [001] volume orientation, but then increases dramatically to about 18 uCcm⁻² from about 50-60% [001] volume orientation. Thus, the inventors have appreciated that ferroelectric materials having crystallographic textures with [001] volume fractions of 50-90% provide enhanced data retention performance.

Although the invention has been illustrated and described with respect to one or more implementations, alterations and/or modifications may be made to the illustrated examples without departing from the spirit and scope of the appended claims. In particular regard to the various functions performed by the above described components or structures (assemblies, devices, circuits, systems, etc.), the terms (including a reference to a “means”) used to describe such components are intended to correspond, unless otherwise indicated, to any component or structure which performs the specified function of the described component (e.g., that is functionally equivalent), even though not structurally equivalent to the disclosed structure which performs the function in the herein illustrated exemplary implementations of the invention. In addition, while a particular feature of the invention may have been disclosed with respect to only one of several implementations, such feature may be combined with one or more other features of the other implementations as may be desired and advantageous for any given or particular application. Furthermore, to the extent that the terms “including”, “includes”, “having”, “has”, “with”, or variants thereof are used in either the detailed description and the claims, such terms are intended to be inclusive in a manner similar to the term “comprising”.

1. A semiconductor device, comprising:
a ferroelectric capacitor comprising:
a conductive lower electrode material formed above a semiconductor body;
a ferroelectric material formed above the lower electrode material, the ferroelectric material comprising unit cells individually comprising an elongated dimension, wherein a percentage of the unit cells are oriented with elongated dimensions substantially normal to a generally planar upper surface of the semiconductor body, and wherein the percentage is about 50% or more and about 70% or less; and
a conductive upper electrode material formed above the ferroelectric material.

2. The device of claim 1, wherein the ferroelectric material comprises PZT.

3. The device of claim 2, wherein the percentage is about 60% or more and about 70% or less.

4. The device of claim 2, wherein the lower electrode material comprises Iridium.

5. (canceled)

6. The device of claim 2, wherein the unit cells of the ferroelectric material have a tetragonal distortion of about 1% or more and about 4% or less.

7. The device of claim 2, wherein the PZT ferroelectric material comprises a Zr content of about 0-52%.

8. The device of claim 7, wherein the PZT ferroelectric material comprises a Zr content of about 10-40%.

9. The device of claim 1, wherein the percentage is about 60% or more and about 70% or less.

10. The device of claim 9, wherein the lower electrode material comprises Iridium.

11. (canceled)

12. The device of claim 1, wherein the lower electrode material comprises Iridium.

13. (canceled)

14. The device of claim 1, wherein the unit cells of the ferroelectric material have a tetragonal distortion of about 1% or more and about 4% or less.

15. A ferroelectric capacitor comprising:
a conductive lower electrode material formed above a semiconductor body;
a ferroelectric material formed above the lower electrode material, the ferroelectric material comprising unit cells individually comprising an elongated dimension; and
a conductive upper electrode material formed above the ferroelectric material;
wherein the upper and lower electrodes are spaced from one another along an axis, wherein a percentage of the unit cells in the ferroelectric material are oriented with elongated dimensions substantially parallel to the axis, and wherein the percentage is about 50% or more and about 70% or less.

16. The ferroelectric capacitor of claim 15, wherein the ferroelectric material comprises PZT.

17. The ferroelectric capacitor of claim 16, wherein the percentage is about 60% or more and about 70% or less.

18. The ferroelectric capacitor of claim 16, wherein the lower electrode material comprises Iridium.

19. (canceled)

20. The ferroelectric capacitor of claim 16, wherein the unit cells of the ferroelectric material have a tetragonal distortion of about 1% or more and about 4% or less.

21. The ferroelectric capacitor of claim 16, wherein the PZT ferroelectric material comprises a Zr content of about 0-52%.

22. The ferroelectric capacitor of claim 16, wherein the PZT ferroelectric material comprises a Zr content of about 10-40%.

23. The ferroelectric capacitor of claim 15, wherein the percentage is about 60% or more and about 70% or less.

24. The ferroelectric capacitor of claim 23, wherein the lower electrode material comprises Iridium.

25. (canceled)

26. The ferroelectric capacitor of claim 15, wherein the lower electrode material comprises Iridium.

27-50. (canceled)
